(19) United States
(12) Patent Application Publication
(10) Pub. No.: US 2009/0167571 A1
(43) Pub. Date: Jul. 2, 2009

(54) THIN-TYPE MODE-SWITCHING SWITCH

(75) Inventor: Hsi-Hsin Loo, Taipei City (TW)

Correspondence Address: STEVENS & SHOWALTER LLP, 7019 CORPORATE WAY, DAYTON, OH, 45459-4238, US

(73) Assignee: ALTEK CORPORATION, Hsinchu (TW)

(21) Appl. No.: 12/141,136

(22) Filed: Jun. 18, 2008

(30) Foreign Application Priority Data
Dec. 28, 2007 (TW) 096222462

(51) Int. Cl. H03M 11/00

(52) U.S. Cl. 341/35

(57) ABSTRACT

A thin-type mode-switching switch includes a circuit board, a metal dome, a mode dial, and a fixing member. The circuit board has a plurality of retaining holes opened therein, and conductive regions are distributed around the retaining holes to serve as switch contacts. When the mode dial is rotated to drive the metal dome, a protruding portion on the metal dome falls in one of the retaining holes. Due to the contact between the protruding portion and the conductive region, a preset input signal is transmitted to a central control unit. Thereby, the mode-switching and retaining control are integrated to achieve the purpose of being thin-type.

### CROSS-REFERENCE TO RELATED APPLICATIONS

This non-provisional application claims priority under 35 U.S.C. §119(a) on Patent Application No. 096222462 filed in Taiwan, R.O.C. on Dec. 28, 2007 the entire contents of which are hereby incorporated by reference.

### BACKGROUND OF THE INVENTION

1. Field of Invention

The present invention relates to a mode-switching switch, and more particularly to a thin-type mode-switching switch applicable to a thin electronic device.

2. Related Art

The type and function of electronic devices become increasingly complicated due to rapid development of technology. The input and operating devices in an electronic device must be improved together with the product, so as to meet the requirement of users. The devices simplest in operation are the key-type, in which a single key is corresponding to a specific function, for example, characters, figures, or preset instructions.

However, as the functions of electronic devices become more and more complicated, the conventional key function lags behind the requirement. Taking digital cameras for example, to meet various photographic requirements of the users, a current digital camera is generally provided with multiple photographic functions, such as static shot mode, dynamic shot mode, night shot mode, and image edition function. Some digital cameras are even provided with further classified modes of settings automatically adjusted according to shooting conditions, like the environment, weather, and brightness, in which the modes of settings are, for example, landscape mode, seaside mode, candlelight mode, and firework mode. Thereby, various photographic functions are integrated into a digital camera, so as to satisfy different requirements of the users. However, if the photographic functions are respectively set to be controlled by an independent key, too many key switches will take up most of the setting space of the digital camera. As a result, the digital camera may become over-sized, and as the control interface is too complicated, it is difficult for the users to figure out the function of each key, thereby causing more difficulties in manipulation. Therefore, a mode dial switch is installed in a digital camera, so as to integrate various photographic functions into a dial structure. Then, the photographic functions required by the users are selected through rotating the mode dial switch, and thus the space taken up by the conventional key switches can be greatly reduced.

Accordingly, Taiwan patent No. 200735154 discloses a mode rotary dial mechanism. The mode rotary dial mechanism includes a circuit board with a mode configuration circuit, a plurality of metal dome foils, and an option button. The metal dome foils, spaced from one another, are disposed on the circuit board and corresponding to the mode configuration circuit. The option button is rotatablely disposed on the circuit board, such that the metal dome foils are connected with the corresponding mode configuration circuit, so as to provide a mode rotary dial mechanism with well contact.

However, for being constituted by a large number of components, the conventional mode rotary dial mechanism has a complicated structure, and the requirements on the precision of manufacturing and assembling are accordingly high, so it is easy to affect the mode-switching function due to poor assembling. Moreover, as plenty of parts are needed, the time taken for assembling is also prolonged, and thus the cost is inevitably increased. Therefore, the manufacturer has to raise the price to balance the cost, and as a result, the consumers have to pay more, which is an undesired situation for both parties.

In addition, as the parts of the mode dial are assembled by stacking, the overall thickness of the product is increased. Thus, it can hardly meet the requirement of thin-type under the current trend of thin and light appearance of the electronic devices.

### SUMMARY OF THE INVENTION

Accordingly, the conventional mode-switching switch simplifies the complicated keys on an electronic device, and integrates multiple functions into a mode dial, so as to facilitate the users to manipulate various functions of the electronic device. However, it is a pity that the mode-switching switch restricted by its structure cannot become thinner along with the light, thin, short, and small trend of the electronic devices.

In view of the above problem, the present invention provides a thin-type mode-switching switch, so as to eliminate the defect in the conventional mode-switching switch that the thickness of the product is increased due to too many parts stacked together. Therefore, in order to meet the design trend of thin electronic devices, the conventional mode-switching switch is simplified by reducing the number of the parts needed. Thereby, the switch and retaining control structures are integrated to achieve the purpose of being thin-type.

Further, the present invention can eliminate poor manufacturing yield caused by too many parts and the resulted complicated structure in the conventional art. In addition, the present invention can also alleviate the difficulties in assembling and shorten the prolonged assembling time due to the large number of parts, thereby reducing the cost.

The present invention provides a thin-type mode-switching switch, which includes a circuit board, a mode dial, a fixing member, and a metal dome. The circuit board has a plurality of retaining holes, and conductive regions are properly distributed around the retaining holes to serve as electrical switches. The retaining holes respectively represent different preset input signals for being electrically connected to a central control unit through conductive regions. The mode dial has an accommodation space covered and fixed on the metal dome. The mode dial and the metal dome are connected to the circuit board through the fixing member, and when the mode dial is rotated, the metal dome is driven to rotate. Further, during the rotation of the metal dome, a protruding portion on the metal dome successively falls into the retaining holes in the circuit board, and contacts with the conductive region around the corresponding retaining hole. Thereby, a preset input signal is transmitted to the central control unit, so as to achieve the purpose of mode-switching.

In the thin-type mode-switching switch according to the present invention, the components and assembling manner thereof are different from those of the conventional mode-switching switch. Thus, the thickness of the product can be reduced, so as to achieve the purpose of being thin-type and further reduce the cost.

### BRIEF DESCRIPTION OF THE DRAWINGS

The present invention will become more fully understood from the detailed description given herein below for illustration only, and thus are not limitative of the present invention, and wherein:

FIG. 1 is an exploded view of a first embodiment of the present invention;

FIG. 2 is a perspective view of the first embodiment of the present invention;

FIG. 3 is an exploded view of a second embodiment of the present invention;

FIG. 4 is a perspective view of the second embodiment of the present invention;

FIG. 5 is a schematic view of a third embodiment of the present invention; and

FIG. 6 is a schematic view of a fourth embodiment of the present invention.

### DETAILED DESCRIPTION OF THE INVENTION

The thin-type mode-switching switch of the present invention is applied to an electronic device, the electronic device which likes a notebook, a mobile communication device (e.g., a cell-phone, a satellite navigation device), a MP3 player, a digital camera, and a personal digital assistant (PDA), but not limit to the above-mentioned computer devices. In the following embodiments, a digital camera is taken as the most preferred embodiment of the present invention. However, the accompanied drawings are used for reference and illustration only, instead of limiting the present invention.

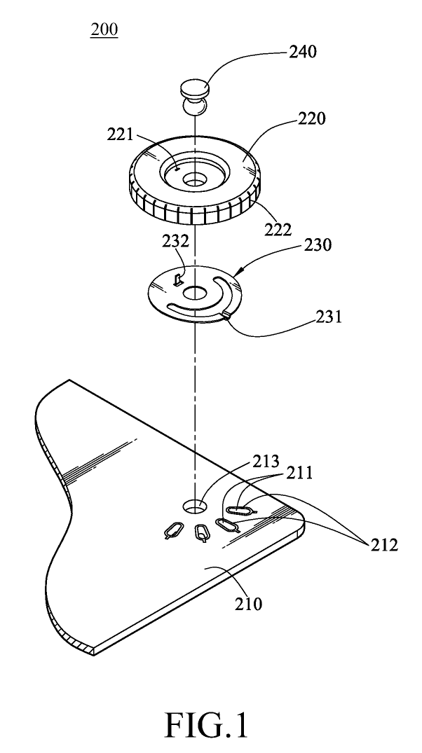

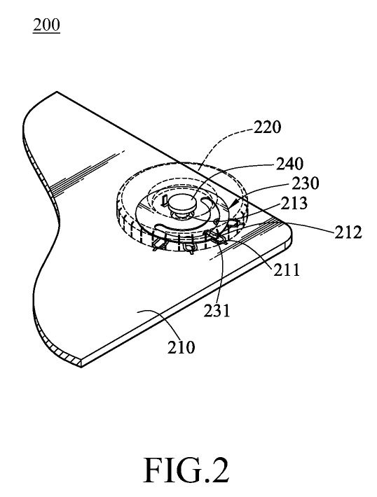

FIGS. 1 and 2 are respectively an exploded view and a perspective view of a thin-type mode-switching switch of a first embodiment of the present invention. As shown in the figures, the thin-type mode-switching switch 200 of the present invention includes a circuit board 210, a mode dial 220, a metal dome 230, and a fixing member 240.

The circuit board 210 has a plurality of retaining holes 211 spaced from one another and a connection hole 213 opened therein. The retaining holes 211 are disposed surrounding the connection hole 213 in a circle, and an electrical connection portion is constituted by conductive regions properly distributed around the retaining holes 211, so as to form a plurality of switch contacts 212. Each switch contact 212 represents a preset input signal, and is electrically connected to a central control unit (not shown) through the electrical connection portion.

The mode dial 220 is in the shape of a disk. The central portion of the mode dial 220 is a groove slightly lower than the outer ring and has a hole opened at the central axis. The central recession portion of the mode dial 220 further has a slot 221 on the edge. Moreover, the mode dial 220 has a plurality of parallel trenches 222 disposed on the outer annulus for anti-slipping, and also has an accommodation space corresponding to the metal dome 230, such that the metal dome 230 can be received in the accommodation space of the mode dial 220.

The metal dome 230 is of an annular structure, with a protruding portion 231 disposed on the periphery, a hole opened at the central axis of the metal dome 230, and a buckling member 232 disposed corresponding to the slot 221 of the mode dial 220 about the central axis.

The fixing member 240 is a buckling unit, which can be inserted into the connection hole 213, for fixing the metal dome 230 and the mode dial 220 on the circuit board 210. The fixing member 240 has a top portion and a central shaft. One end of the central shaft is connected to the top portion, and the other end opposite to the top portion has a diameter slightly larger than that of the connection hole 213 in the circuit board 210. The central shaft has a smooth axial surface, and is fixed in the connection hole 213 of the circuit board 210 by buckling. Alternatively, the fixing member 240 is directly fixed in the connection hole 213 of the circuit board 210 by welding.

The metal dome 230 is placed in the accommodation space of the mode dial 220. Taking the central axis of the metal dome 230 as the center point, the buckling member 232 on the metal dome 230 is aligned with the slot 221 in the central recession portion of the mode dial 220, and is engaged thereto, such that the metal dome 230 is fixed in the accommodation space of the mode dial 220. After the mode dial 220 is engaged with the metal dome 230, the protruding portion 231 of the metal dome 230 is placed in any of the retaining holes 211, and the central axis of the mode dial 220 and the metal dome 230 is aligned with that of the connection hole 213 in the circuit board 210. After penetrating the hole of the mode dial 220 and the metal dome 230, the central shaft of the fixing member 240 is inserted in the connection hole 213 of the circuit board 210 till being engaged to the circuit board 210. Thereby, the mode dial 220 and the metal dome 230 are connected to the circuit board 210 through the fixing member 240, and the assembling of the mode-switching switch 200 is finished.

After the assembling of the mode-switching switch 200, when the mode dial 220 is rotated clockwise or anticlockwise, the metal dome 230 is driven to rotate. Further, during the rotation of the metal dome 230, the protruding portion 231 thereon falls in one of the retaining holes 211, and causes the feeling of being retained. In addition, as the protruding portion 231 of the metal dome 230 contacts with the switch contact 212 formed by the conductive region around the corresponding retaining hole 211, a preset input signal is transmitted to the central control unit (not shown).

When the mode dial 220 is continuously rotated clockwise or anticlockwise to other positions, the protruding portion 231 on the metal dome 230 may successively fall in other retaining holes 211 along with the rotation. Thereby, besides causing the aforementioned retaining feeling, another preset input signal is transmitted to the central control unit (not shown), so as to achieve the purpose of mode-switching.

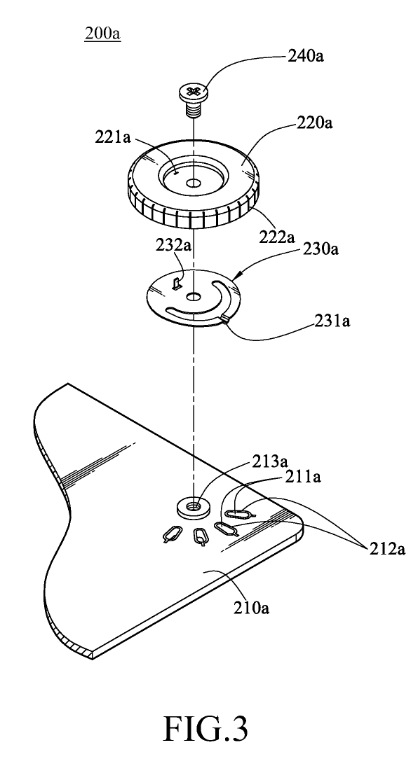

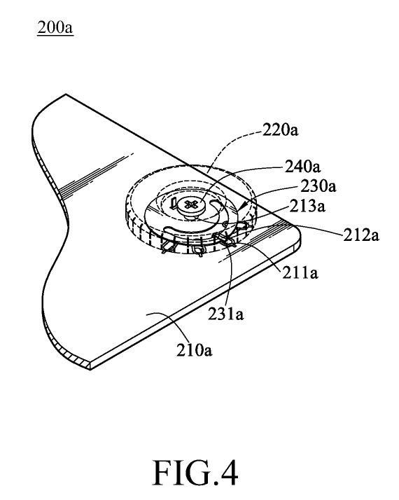

FIGS. 3 and 4 are respectively an exploded view and a perspective view of a thin-type mode-switching switch of a second embodiment of the present invention. As shown in the figures, the thin-type mode-switching switch 200a of the present invention includes a circuit board 210a, a mode dial 220a, a metal dome 230a, and a fixing member 240a.

The circuit board 210a has a plurality of retaining holes 211a spaced from one another and a metal shaft 213a. The metal shaft 213a is threaded therein for locking the fixing member 240a. The retaining holes 211a are disposed surrounding the metal shaft 213a in a circle, and an electrical connection portion is constituted by conductive regions properly distributed around the retaining holes 211a, so as to form a plurality of switch contacts 212a. Each switch contact 212a represents a preset input signal, and is electrically connected to a central control unit (not shown) through the electrical connection portion.

The mode dial 220a is in the shape of a disk. The central portion of the mode dial 220a is a groove slightly lower than the outer ring and has a hole opened at the central axis. The central recession portion of the mode dial 220a further has a slot 221a opened on the edge. Moreover, the mode dial 220a has a plurality of parallel trenches 222a disposed on the outer annulus for anti-slipping, and also has an accommodation space corresponding to the metal dome 230a, such that the metal dome 230a can be received in the accommodation space of the mode dial 220a.

The metal dome 230a is of an annular structure, with a protruding portion 231a disposed on the periphery, a hole opened at the central axis of the metal dome 230a, and a buckling member 232a disposed corresponding to the slot 221a of the mode dial 220a about the central axis.

The fixing member 240a is a screw, which can be inserted into the metal shaft 213a, for fixing the metal dome 230a and the mode dial 220a on the circuit board 210a. The fixing member 240a has a top portion and a central shaft, in which one end of the central shaft is connected to the top portion. The upper portion of the central shaft is smooth, about which the mode dial 220a and the metal dome 230a rotate, and the lower portion of the central shaft is threaded, so as to be fixed in the metal shaft 213a of the circuit board 210a by locking.

The metal dome 230a is placed in the accommodation space of the mode dial 220a. Taking the central axis of the metal dome 230a as the center point, the buckling member 232a on the metal dome 230a is aligned with the slot 221a in the central recession portion of the mode dial 220a, and is engaged thereto, such that the metal dome 230a is fixed in the accommodation space of the mode dial 220a. After the mode dial 220a is engaged with the metal dome 230a, the protruding portion 231a of the metal dome 230a is placed in any of the retaining holes 211a, and the central axis of the mode dial 220a and the metal dome 230a is aligned with that of the metal shaft 213a in the circuit board 210a. After penetrating the hole of the mode dial 220a and the metal dome 230a, the central shaft of the fixing member 240a is locked in the metal shaft 213a of the circuit board 210a till being locked to the circuit board 210a. Thereby, the mode dial 220a and the metal dome 230a are connected to the circuit board 210a through the fixing member 240a, and the assembling of the mode-switching switch 200a is finished.

After the assembling of the mode-switching switch 200a, the operation thereof is identical to that of the mode-switching switch 200 in the first embodiment.

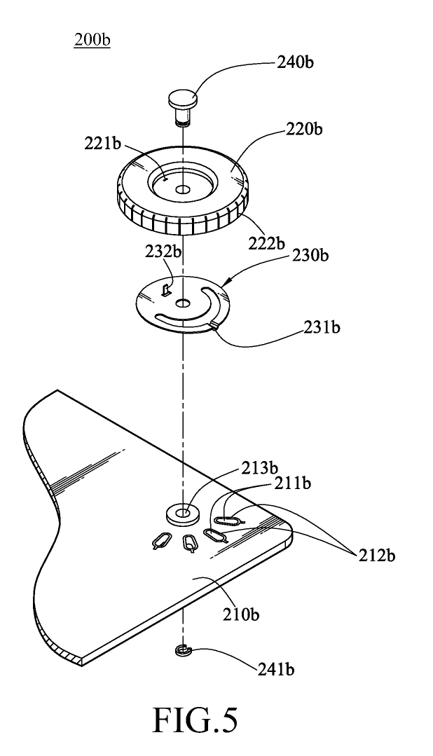

FIG. 5 is a schematic view of a thin-type mode-switching switch of a third embodiment of the present invention. Referring to FIG. 5, the thin-type mode-switching switch 200b of the present invention includes a circuit board 210b, a mode dial 220b, a metal dome 230b, and a fixing member 240b.

The difference between the third and the first embodiment is that, the fixing member 240b is a buckling unit having a top portion and a central shaft. One end of the central shaft is connected to the top portion. The axial surface of the central shaft is smooth, about which the mode dial 220b and the metal dome 230b rotate. The other end of the central shaft opposite to the top portion has two grooves, to be engaged by a C-shaped buckle 241b.

The metal dome 230b is placed in the accommodation space of the mode dial 220b. Taking the central axis of the metal dome 230b as the center point, a buckling member 232b on the metal dome 230b is aligned with a slot 221b in the central recession portion of the mode dial 220b, and is engaged thereto, such that the metal dome 230b is fixed in the accommodation space of the mode dial 220b. After the mode dial 220b is engaged with the metal dome 230b, a protruding portion 231b of the metal dome 230b is placed in any of retaining holes 211b, and the central axis of the mode dial 220b and the metal dome 230b is aligned with that of a connection hole 213b in the circuit board 210b. After penetrating the hole of the mode dial 220b and the metal dome 230b, the central shaft of the fixing member 240b is engaged in the two grooves of the fixing member 240b through the C-shaped buckle 241b. Thereby, the mode dial 220b and the metal dome 230b are connected to the circuit board 210b through the fixing member 240b and the C-shaped buckle 241b, and the assembling of the mode-switching switch 200b is finished.

After the assembling of the mode-switching switch 200b, the operation thereof is identical to that of the mode-switching switch 200 in the first embodiment.

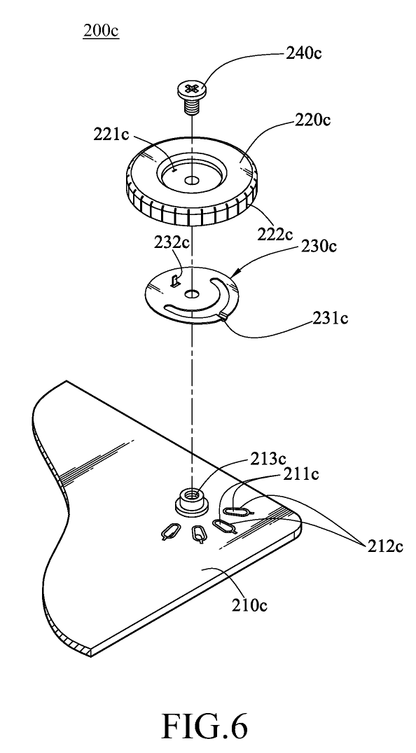

FIG. 6 is a schematic view of a thin-type mode-switching switch of a fourth embodiment of the present invention. Referring to FIG. 6, the thin-type mode-switching switch 200c of the present invention includes a circuit board 210c, a mode dial 220c, a metal dome 230c, and a fixing member 240c.

The difference between the fourth and the second embodiment is that, the circuit board 210c has a plurality of retaining holes 211c spaced from one another and a connection hole 213c opened therein. The connection hole 213c is threaded therein for locking the fixing member 240c. The retaining holes 211c are disposed surrounding the connection hole 213c in a circle, and an electrical connection portion is constituted by conductive regions properly distributed around the retaining holes 211c, so as to form a plurality of switch contacts 212c. Each switch contact 212c represents a preset input signal, and is electrically connected to a central control unit (not shown) through the electrical connection portion.

The metal dome 230c is placed in the accommodation space of the mode dial 220c. Taking the central axis of metal dome 230c as the center point, the buckling member 232c on the metal dome 230c is aligned with the slot 221c in the central recession portion of the mode dial 220c, and is engaged thereto, such that the metal dome 230c is fixed in the accommodation space of the mode dial 220c. After the mode dial 220c is engaged with the metal dome 230c, a protruding portion 231c of the metal dome 230c is placed in any of the retaining holes 211c, and the central axis of the mode dial 220c and the metal dome 230c is aligned with that of the connection hole 213c in the circuit board 210c. After penetrating the hole of the mode dial 220c and the metal dome 230c, the central shaft of the fixing member 240c is locked in the connection hole 213c of the circuit board 210a till being locked to the circuit board 210c. Thereby, the mode dial 220c and the metal dome 230c are connected to the circuit board 210c through the fixing member 240c, and the assembling of the mode-switching switch 200c is finished.

After the assembling of the mode-switching switch 200c, the operation thereof is identical to that of the mode-switching switch 200a in the second embodiment.

What is claimed is:

1. A thin-type mode-switching switch, comprising:
a circuit board, having a plurality of retaining holes and a connection hole opened therein, wherein conductive regions are distributed around the retaining holes to serve as switch contacts;
a metal dome, having a protruding portion and a buckling member;
a mode dial, having a slot, wherein the metal dome is fixed to the mode dial by engaging the buckling member into the slot; and
a fixing member, wherein the fixing member is inserted in the connection hole, for fixing the metal dome and the mode dial on the circuit board.

2. The thin-type mode-switching switch as claimed in claim 1, wherein the connection hole is a metal shaft.

3. The thin-type mode-switching switch as claimed in claim 1, wherein the connection hole is threaded therein.

4. The thin-type mode-switching switch as claimed in claim 1, wherein a plurality of parallel trenches is disposed on outer annulus of the mode dial.

5. The thin-type mode-switching switch as claimed in claim 1, wherein the mode dial has an accommodation space for receiving the metal dome.

6. The thin-type mode-switching switch as claimed in claim 1, wherein the fixing member is a buckling unit.

7. The thin-type mode-switching switch as claimed in claim 1, wherein the fixing member is a screw.

8. The thin-type mode-switching switch as claimed in claim 1, wherein the fixing member is welded in the connection hole.

9. The thin-type mode-switching switch as claimed in claim 6, wherein the other end of a central shaft of the buckling member opposite to a top portion has two grooves, to be engaged with a C-shaped buckle.
